(19) United States
(12) Patent Application Publication
(10) Pub. No.: US 2008/0264482 A1
(43) Pub. Date: Oct. 30, 2008

(54) DYE-SENSITIZED SOLAR CELL MODULE AND THE MANUFACTURING METHOD USING CARBON NANOTUBE ELECTRODE

(75) Inventors: Dong Yoon Lee, Changwon-si (KR); Won Jae Lee, Geumjeong-gu (KR); Jae Sung Song, Changwon-si (KR); Bo Kun Koo, Sasang-gu (KR); Hyun Ju Kim, Milyang-si (KR)

Correspondence Address: Hyun Jong Park;TUCHMAN & PARK LLC, 41 White Birch Road, Redding, CT, 06896-2209, US

(73) Assignee: Korea Electrotechnology Research Institute, Changwon-si (KR)

(21) Appl. No.: 11/871,993

(22) Filed: Oct. 13, 2007

Related U.S. Application Data
(63) Continuation of application No. PCT/KR2006/005135, filed on Nov. 30, 2006.

(30) Foreign Application Priority Data
Nov. 30, 2005 (KR) 10-2005-0115361
Nov. 30, 2006 (KR) 10-2006-0019439

(51) Int. Cl. H01L 31/00

(52) U.S. Cl. 136/256

(57) ABSTRACT

Disclosed herein is a dye-sensitized solar cell module having carbon nanotube electrodes, the solar cell module comprising: upper and lower transparent substrates; conductive transparent electrodes formed on the inner surfaces of the upper and lower transparent substrates; a plurality of porous oxide semiconductor negative electrodes formed on the upper conductive transparent electrode at a constant interval and having a dye adsorbed on the surface thereof; counter electrodes formed on the lower conductive transparent electrode in a thin film form and made of a carbon nanotube layer as a positive electrode portion corresponding to the negative electrodes; grid electrodes formed on the upper and lower conductive transparent electrodes between unit electrodes, each consisting of the negative electrode and the counter electrode corresponding thereto, the grid electrodes serving to collect electrons generated by photosensitization; connecting electrodes formed on the upper and lower conductive transparent electrodes and electrically connected with the grid electrode so as to transfer electrons moved from the grid electrodes to the outside; and electrolyte placed between the negative electrodes and the counter electrodes. Also disclosed is a method for manufacturing the solar cell module. According to the disclosed invention, a high-efficiency, large-area, dye-sensitized solar cell comprising carbon nanotubes is realized by forming a plurality of dye-sensitized solar cell units in a module arrangement, and forming grid electrodes and connection electrodes for the collection and movement of electrons. Thus, the disclosed invention has high practical utility.

### REFERENCE TO RELATED APPLICATIONS

This is a continuation of pending International Patent Application PCT/KR2006/005135 filed on Nov. 30, 2006, which designates the United States and claims priority of Korean Patent Applications No. 10-2005-0115361 filed on Nov. 30, 2005, and No. 10-2006-0119439 filed on Nov. 30, 2006, the entire contents of which are incorporated herein by reference.

### FIELD OF THE INVENTION

The present invention relates to a dye-sensitized solar cell module having carbon nanotube electrodes, and more particularly to a large-area, high-efficiency, dye-sensitized solar cell module, in which a plurality of dye-sensitized solar cell units are connected to each other, and grid electrodes and connecting electrodes for the collection and movement of electrons are formed.

### BACKGROUND OF THE INVENTION

In general, a dye-sensitized solar cell is a kind of solar cell that chemically generates electricity using the solar cell absorption capability of dyes, and comprises, on a glass substrate, a negative electrode, a dye, an electrolyte, a transparent conductive electrode and the like. The negative electrode consists of an n-type oxide semiconductor having a wide bandgap, for example, TiO₂, ZnO or SnO₂, which are present in the form of a nanoporous film. On the surface of the negative electrode, a monomolecular dye layer is adsorbed.

When solar light is incident on the solar cell, electrons having the Fermi energy in the dye will be excited to a higher energy level by absorbing the solar energy. At this time, an empty orbital having a lower energy level, from which electrons left, will be filled again with electrons when it receives electrons from ions in the electrolyte. The ions which provided electrons to the dye will migrate to the counter electrode as a positive electrode, in which the ions will receive electrons. At this time, the counter electrode in the positive electrode portion will act as a catalyst for the oxidation-reduction reaction of ions in the electrolyte to provide electrons to the ions in the electrolytes through an oxidation-reduction reduction on the electrode surface.

To satisfy this action of the counter electrode, as the counter electrode in the prior dye-sensitized solar cells, a platinum thin film having excellent catalytic action is mainly used. In some cases, an electrode made of a noble metal having properties similar to those of platinum, for example, palladium, silver or gold, or a carbon-based electrode made of carbonaceous material such as carbon black or graphite, is used.

The platinum electrode has high electrical conductivity and excellent catalytic properties, but it is expensive, and has limited ability to increase the catalytic reaction rate of the cell, because it encounters a limitation in its ability to increase the surface area thereof, on which catalytic action occurs. The carbon-based electrode is inexpensive and it is possible to increase the surface area thereof more than when using the platinum electrode, but it has a problem in that the catalytic reaction rate thereof is slower than that of the platinum electrode, thus reducing the efficiency of the solar cell.

When an insulator substrate made of, for example, a ceramic material, is used as a substrate, the prior platinum electrode should be formed to a large thickness in order to satisfy electrical conductivity required in the cell, and in this case, a high cost is incurred, thus making it impossible to actually use a substrate made of an insulating material.

To solve this problem, the use of a carbon nanotube electrode as the counter electrode has been suggested. The carbon nanotube electrode consisting of a carbon nanotube layer has not only excellent electrical conductivity, but also excellent catalytic properties, and thus increases the efficiency of the dye-sensitized solar cell. This carbon nanotube electrode is expected to be widely used as a counter electrode in dye-sensitized solar cells.

When the prior dye-sensitized solar cell comprising the carbon nanotube electrode as the counter electrode is made in the form of a small unit cell having a size of less than 1 cm×1 cm, it is not difficult for the solar cell to obtain an efficiency of more than 5%, and the highest efficiency of the dye-sensitized solar cell made in the form of the small unit cell is 11%. However, when it is fabricated in the form of a large-area cell having a size of more than 1 cm×1 cm, it is almost impossible for the large-area cell to obtain an efficiency of more than 5%.

The reason why the large-area cell has such low efficiency is because of a negative electrode consisting of a nanoporous oxide semiconductor, used in the dye-sensitized solar cell. Generally, in semiconductor-type solar cells, exemplified by a silicon (Si) solar cell, electrons and holes, produced by photoelectric conversion, migrate under the action of an electromagnetic field, and the path for the migration is larger than the mean free path distance. Thus, electrons can migrate in the semiconductor or the electrode without special interference.

However, when electrons migrate in an electrode formed by the connection of nanoparticles, the electrons will not move the mean free path distance, as in the dye-sensitized solar cell. This is because the size of the nanoparticles is smaller than the mean free path distance of the electrons, and thus the distance that the electrons migrate from one grain boundary to the other grain boundary of the nanoparticles is smaller than the mean free path distance of the electrons. If the electrons do not migrate the mean free path distance as described above, the electrons will be hardly influenced at all by the electromagnetic field acting on the solar cell. In this case, the migration of electrons will be determined by diffusion resulting from the hopping migration between the nanoparticles, rather than free migration resulting from the electromagnetic field.

The migration of electrons by diffusion means that the electrons migrate from high concentration to low concentration, that the electrons have a low migration rate, and that the electrons move three-dimensionally depending on the concentration gradient, rather than in one direction.

Thus, because the movement of electrons in the dye-sensitized solar cell is much slower than in the semiconductor-type solar cell, and is restricted by nanoparticles, if the diffusion distance of electrons or the area of the cell increases, electrons will have a small possibility of reaching the transparent conductive electrode, which transfers electrons from the nanoporous oxide semiconductor negative electrode to the outside. Thus, as the area of the solar cell becomes larger and the thickness of the nanoporous oxide semiconductor negative electrode becomes larger, the efficiency of the solar cell is decreased. In the dye-sensitized solar cell, it is generally known that the decrease in the efficiency thereof starts to appear from a horizontal distance of more than 5 mm and a thickness of more than 10 μm.

For this reason, in fabricating a large-area module having good efficiency, unit cells are generally connected to each other using connecting electrodes. Alternatively, a grid electrode for efficiently electrons is inserted in the unit cell.

In the prior art, the grid electrodes or connecting electrodes are made mainly of a metal such as platinum, silver, gold or nickel. Such metal-based grid electrodes or connecting electrodes have problems in that, because they are dissolved by reaction with an electrolyte, they must be completely insulated, making the preparation thereof difficult, and it is difficult to use in a substrate requiring flexibility, such as a plastic substrate. Also, it entails a high production cost, making mass production difficult. Accordingly, there is a need to develop a novel electrode, which is chemically stable and, at the same time, flexible.

### SUMMARY OF THE INVENTION

The present invention has been made in order to solve the above-described problems occurring in the prior art, and it is an object of the present invention to provide a large-area, high-efficiency, dye-sensitized solar cell module comprising carbon nanotube electrodes, in which a plurality of dye-sensitized solar cell units is connected in parallel or in series, and in which grid electrodes and connecting electrodes are formed for the collection and movement of electrons, as well as a manufacturing method thereof.

Another object of the present invention is to provide a dye-sensitized solar cell module comprising carbon nanotube electrodes, in which counter electrodes, grid electrodes and connecting electrodes are formed of carbon nanotube electrodes, such that the solar cell module is electrically and chemically stable, as well as a manufacturing method thereof.

To achieve the above objects, the present invention provides a dye-sensitized solar cell module having carbon nanotube electrodes, the solar cell module comprising: upper and lower transparent substrates; conductive transparent electrodes formed on the inner surfaces of the upper and lower transparent substrates; a plurality of porous oxide semiconductor negative electrodes formed on the upper conductive transparent electrode at a constant interval and having a dye adsorbed on the surface thereof; counter electrodes formed on the lower conductive transparent electrode in a thin film form and made of a carbon nanotube layer as a positive electrode portion corresponding to the negative electrodes; grid electrodes formed on the upper and lower conductive transparent electrodes between unit electrodes, each consisting of the negative electrode and the counter electrode corresponding thereto, the grid electrodes serving to collect electrons generated by photosensitization; connecting electrodes formed on the upper and lower conductive transparent electrodes and electrically connected with the grid electrode so as to transfer electrons moved from the grid electrodes to the outside; and electrolyte placed between the negative electrodes and the counter electrodes.

According to a preferred embodiment of the present invention, in the dye-sensitized solar cell module having carbon nanotube electrodes, the grid electrodes on the negative electrode side and the grid electrodes on the counter electrode side are electrically insulated from each other, such that the unit electrodes are connected to each other in parallel. According to another preferred embodiment of the present invention, an etched insulating pattern is formed in the upper and lower conductive transparent electrodes, such that the unit electrodes are electrically insulated from each other through the etched insulating pattern formed in the upper and lower conductive transparent electrodes, such that electricity flows through the grid electrodes, whereby the unit electrodes are connected to each other in series.

Also, in the dye-sensitized solar cell module having carbon nanotube electrodes, an insulating film for electrical insulation is preferably further formed in the electrolyte between the unit electrodes. The insulating film is made of a thermosetting or UV-curable adhesive or a carbon nanotube insulation layer containing the adhesive. The carbon nanotube insulation layer preferably has an electrical resistance of more than 1 kΩcm. Herein, the carbon nanotube insulation layer preferably has a composition in which a non-conductive polymer binder, such as CMC or PVDF, and a non-conductive inorganic material, including SiO₂ or TiO₂, are added to carbon nanotubes in an amount of more than 10 wt %.

Preferably, in the dye-sensitized solar cell module comprising the unit cells connected in parallel, the unit electrodes constitute a plurality of sections, and an etched insulating pattern is formed in the upper and lower conductive transparent electrodes, such that the sections are electrically insulated from each other.

Also, the dye-sensitized solar cell module having carbon nanotube electrode preferably further comprises an insulating film for electrical insulation formed in the electrolyte between the unit electrodes. The insulating film is made of a thermosetting or UV-curable adhesive or a carbon nanotube insulation layer containing the adhesive. The carbon nanotube insulation layer preferably has an electrical resistance of more than 1 kΩcm.

Moreover, the carbon nanotube insulation layer preferably has a composition in which a non-conductive polymer binder such as CMC and PVDF, and a non-conductive inorganic material including SiO₂ and TiO₂, are added to the carbon nanotubes in an amount of more than 10%.

The carbon nanotube electrode consisting of the carbon nanotube layer preferably has an electrical conductivity of 10⁻¹ to 10⁴ Ω⁻¹cm⁻¹.

Also, the grid electrode or the connecting electrodes preferably consist of a carbon nanotube layer.

Herein, a carbon nanotube paste for preparing the carbon nanotube layer is preferably prepared by mixing carbon nanotubes with a carbon- or metal-based additive or a polymer binder such as CMC (carboxyl methyl cellulose) or PVDF in a mechanical or mechanochemical manner, including a ball mill, a high-energy ball mill, ultrasonic waves, a grinder, and a V-mixer. The content of the binder in the paste is preferably 0.5-90 wt %.

In addition, the carbon nanotube layer is formed in a dotted pattern, a linear pattern or a planar pattern using film forming methods, including a doctor blade method, a screen printing method, a spray method, a spin coating method, and a painting method, and has a thickness of 100 nm to 1 mm.

### ADVANTAGEOUS EFFECTS

According to the present invention, a high-efficiency, large-area, dye-sensitized solar cell having carbon nanotubes can be provided by forming a plurality of dye-sensitized solar cell units in a module arrangement, and forming grid electrodes and connection electrodes for the collection and movement of electrons. Thus, the present invention has high practical utility. Moreover, because counter electrodes, grid electrodes and connecting electrodes in the cell module are made of flexible and electrically conductive carbon nanotube electrodes, these electrodes do not undergo dissolution in an electrolyte, and deterioration resulting from oxidation or the like, which are problems with the prior metal electrodes. Thus, an electrically and chemically stable solar cell module can be provided.

### BRIEF DESCRIPTION OF THE DRAWINGS

FIG. 1 schematically shows the structure of a dye-sensitized solar cell unit used in a dye-sensitized solar cell module comprising carbon nanotubes according to the present invention;

FIG. 2 shows photographs of various carbon nanotubes used in a carbon nanotube electrode in the dye-sensitized solar cell module of FIG. 1;

FIG. 3 is an electron microscope photograph of metal-based carbon nanotubes used in the present invention;

FIG. 4 is a cross-sectional view showing a first embodiment according to the present invention;

FIG. 5 is a decomposed front view with respect to upper and lower transparent substrates according to a first embodiment of the present invention. (a): upper transparent substrate; and (b): lower transparent substrate;

FIG. 6 is a cross-sectional view showing a second embodiment of the present invention;

FIG. 7 is a block diagram showing a method for manufacturing a dye-sensitized solar cell module using carbon nanotubes according to the present invention;

FIG. 8 is an electron microscope photograph of a carbon nanotube electrode layer formed using multi-wall carbon nanotubes and CMC binder, according to the present invention;

FIG. 9 is a photograph of carbon nanotube electrode film samples prepared such that they show a transmission rate ranging from transparency to opacity on a glass substrate having no electrical conductivity;

FIG. 10 shows a process in which a carbon nanotube paste used in the present invention is prepared using a ball mill, and shows spherical and cylindrical balls used in mixing;

FIG. 11 shows the operating principle of a dye-sensitized solar cell device having carbon nanotubes;

FIG. 12 shows the measurement results of cyclic voltammetry (CV) of the oxidation-reduction reaction of an electrolyte for the prior platinum electrode and a carbon nanotube electrode;

FIG. 13 shows impedance characteristics appearing when an alternating current voltage of 100 mHz-100 kHz is applied in a state in which a direct current voltage of −0.5V was applied to the prior platinum electrode and a carbon nanotube electrode such that a reaction can occur;

FIG. 14 shows the results of cyclic voltammetry (CV) measurement conducted at the initial stage and after 15 days of an oxidation-reduction reaction of an electrolyte in order to assess the stabilities of the prior platinum electrode and the carbon nanotube electrode;

FIG. 15 shows impedance characteristics measured at the initial stage and 15 days after cell fabrication in order to assess the stabilities of the prior platinum electrode and the carbon nanotube electrode;

FIG. 16 shows the impedance spectral characteristics of three different carbon nanotubes;

FIG. 17 shows the change in solar cell efficiency as a function of the optical wavelengths of the prior platinum electrode and the carbon nanotube electrode; and

FIG. 18 shows the efficiency of a dye-sensitized solar cell module comprising carbon nanotube electrodes connected in parallel.

### DESCRIPTION OF REFERENCE NUMERALS

101 and 102: upper and lower transparent substrates;
103 and 104: upper and lower conductive transparent electrodes;
105: porous negative electrodes; 106: counter electrodes;
107: grid electrodes; 108: connecting electrodes;
109: electrolyte; 111: insulating film;
121: etched insulating pattern;
201: multi-wall carbon nanotube; and
202 and 203: carbon nanofibers.

### DETAILED DESCRIPTION OF THE INVENTION

Hereinafter, embodiments of the present invention will be described in detail with reference to the accompanying drawings.\

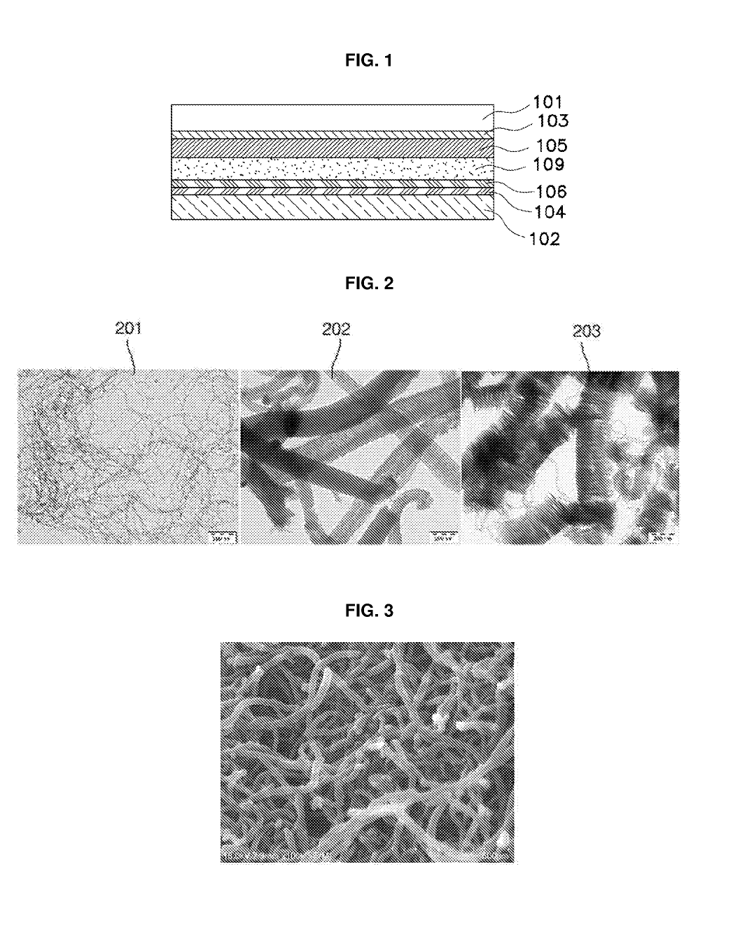

FIG. 1 schematically shows the structure of a dye-sensitized solar cell unit used in a dye-sensitized solar cell solar cell module comprising carbon nanotubes according to the present invention.

Referring to FIG. 1, the dye-sensitized solar cell comprising carbon nanotubes according to the present invention has the form of a large-area module, in which a plurality of general dye-sensitized solar cell units are electrically connected to each other in parallel or in series, and grid electrodes 107 and connecting electrodes 108 are formed in order to increase the efficiency of such dye-sensitized solar cell units, and electrically connect the units to each other in parallel or series.

Specifically, the dye-sensitized solar cell module comprises: upper and lower transparent substrates 101 and 102, made of a glass or transparent plastic material; upper and lower conductive transparent electrodes 103 and 104, made of ITO, SnO₂ or ZnO, formed on the inner surfaces (lower surfaces in the drawing) of the upper and lower transparent substrates 101 and 102; a plurality of porous oxide semiconductor (e.g., TiO₂, SnO₂, ZnO, etc.) negative electrodes 105 formed on the surface (lower surface in the drawing) of the upper conductive transparent electrode 103 at a constant interval and having a dye adsorbed on the surface thereof; counter electrodes 106 formed on the lower conductive transparent substrate in the form of a thin film and made of a carbon nanotube layer as a positive electrode portion corresponding to the porous negative electrodes 105; grid electrodes 107 formed on the upper and lower conductive transparent electrodes 103 and 104 between unit electrodes, each consisting of the negative electrode and the counter electrode 106 corresponding thereto; connecting electrodes 108 formed on the upper and lower conductive transparent electrodes 103 and 104 and electrically connected with the grid electrodes 107; and an electrolyte 109 (consisting of liquid electrolyte, polymer gel or p-type semiconductor) placed between the negative electrodes and the counter electrodes 106.

In the dye-sensitized solar cell module according to the present invention, the counter electrodes 106 are carbon nanotube electrodes consisting of the carbon nanotube layer, and the carbon nanotube electrodes are used to maximize oxidation-reduction reactions on the surfaces of the counter electrodes 106.

Also, the grid electrodes 107 and the connecting electrodes 108 can be made of a metal, such as platinum, silver, gold or nickel, but preferably consist of electrodes, which do not undergo dissolution in the electrolyte 109, or deterioration resulting from oxidation, etc., which are problems occurring with metal electrodes. More preferably, these electrodes are carbon nanotube electrodes consisting of a carbon nanotube layer that is the same as that of the counter electrodes. Thus, an electrically and chemically stable module can be provided.

Herein, as carbon nanotubes forming the carbon nanotube electrodes of the counter electrodes 106, the grid electrodes 107 and the connecting electrodes 108, it is possible to use either single-wall carbon nanotubes, or multi-wall carbon nanotubes 201 or carbon nanofibers 202 and 203 as shown in FIG. 2, or metal-carbon nanotubes as shown in FIG. 3.

Among the carbon nanotubes adopted in the present invention, carbon nanotubes showing particularly excellent properties are metal-carbon carbon nanotubes. As can be seen in FIG. 3, in the metal-carbon nanotubes, carbon nanotube strands are chemically bound to each other, so that the carbon nanotubes are mixed with metal carbide catalysts used in the preparation thereof, and thus they are connected with each other in a branch arrangement.

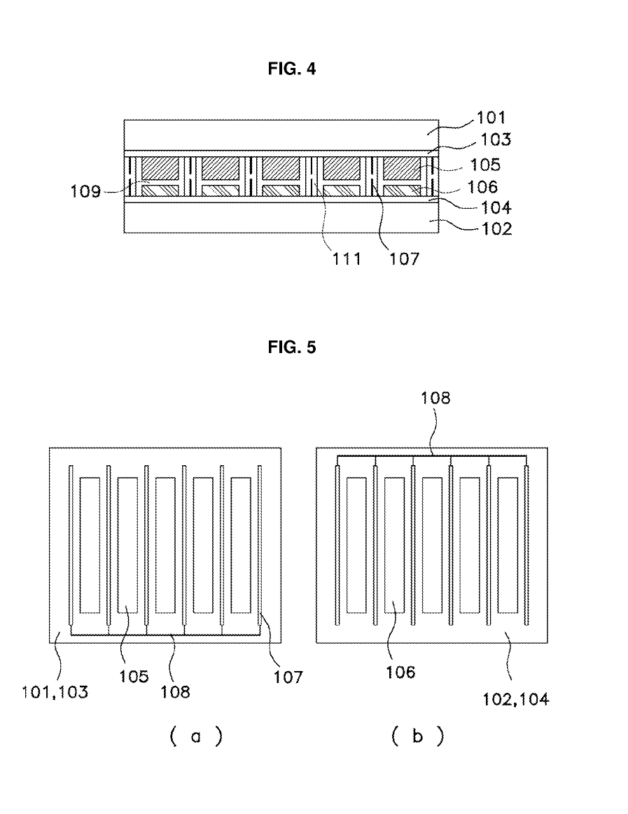

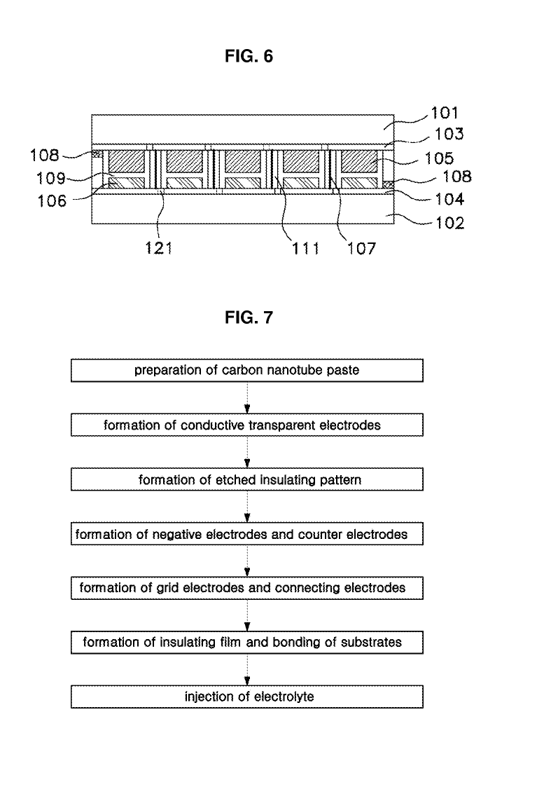

FIGS. 4, 5 and 6 show dye-sensitized solar cell modules manufactured using dye-sensitized solar cell units comprising the above-described carbon nanotubes. Specifically, FIGS. 4 and 5 show a dye-sensitized solar cell module according to a first embodiment of the present invention, and FIG. 6 shows a dye-sensitized solar cell module according to a second embodiment of the present invention. FIG. 7 is a block diagram showing a method for manufacturing the dye-sensitized solar cell module using carbon nanotubes according to the present invention.

As shown in FIGS. 4 and 5, the dye-sensitized solar cell module having carbon nanotube electrodes, according to the first embodiment of the present invention, comprises: the upper and lower transparent substrates 101 and 102; the conductive transparent electrodes formed on the inner surfaces of the upper and lower transparent substrates 101 and 102; the plurality of porous oxide semiconductor negative electrodes 105 formed on the upper conductive transparent electrode 103 at a constant interval and having a dye adsorbed on the surface thereof; the counter electrodes 106 formed on the lower conductive transparent electrode 104 in a thin film form and made of a carbon nanotube layer as a positive electrode portion corresponding to the negative electrodes; the grid electrodes 107 formed on the upper and lower conductive transparent electrodes 103 and 104 between unit electrodes, each consisting of the negative electrode and the counter electrode 106 corresponding thereto; the connecting electrodes 108 formed on the upper and lower conductive transparent electrodes 103 and 104 and electrically connected with the grid electrodes 107; and the electrolyte 109 placed between the negative electrodes and the counter electrodes 106, in which the grid electrodes 107 on the negative electrode side, and the grid electrodes 107 on the counter electrode side, are electrically connected to each other, so that the unit electrodes are connected to each other in parallel.

In other words, the unit electrodes consisting of the plurality of negative electrodes and the counter electrodes 106 are formed on the large-area upper and lower transparent substrates 101 and 102, and the grid electrodes 107 are formed between the unit electrodes, in such a way that the grid electrode 107 on the negative electrode side are electrically connected with the negative electrodes, the grid electrodes 107 on the counter electrode side 107 are electrically connected with the counter electrodes 106, and the unit electrodes are electrically connected with the upper and lower conductive transparent electrodes 103 and 104, so that the dye-sensitized solar cell units are connected to each other in parallel.

Preferably, the unit electrodes form a plurality of sections, and etched insulating patterns 121 are formed on the upper and lower conductive transparent electrodes 103 and 104, such that the sections are insulated from each other. In other words, in the case where a plurality of combinations of the unit electrodes are formed, the upper surfaces of the upper and lower conductive transparent electrodes 103 and 104 are etched in the desired pattern in order to electrically insulate the unit electrodes of one combination from the unit electrodes of other combinations.

As shown in FIG. 6, the dye-sensitized solar cell module having carbon nanotube electrodes, according to the second embodiment of the present invention, comprises: the upper and lower transparent substrates 101 and 102; the conductive transparent electrodes on the inner surfaces of the upper and lower transparent electrodes 103 and 104; the plurality of porous oxide semiconductor negative electrodes 105 formed on the upper conductive transparent electrode 103 at a constant interval and having a dye formed on the surface thereof; the counter electrodes 106 formed on the lower conductive transparent electrode 104 in a thin film form and made of a carbon nanotube layer as a positive electrode portion corresponding to the negative electrodes; the grid electrodes 107 formed on the upper and lower conductive transparent electrodes 103 and 104 between unit electrodes, each consisting of the negative electrode and the counter electrode 106 corresponding thereto; the connecting electrodes 108 formed on the upper and lower conductive transparent electrodes 103 and 104 and electrically connected with the grid electrodes 107; and the electrolyte 109 placed between the negative electrodes and the counter electrodes 106, wherein an etched insulating pattern is formed in the upper and lower conductive transparent electrodes 103 and 104, such that the unit electrodes are electrically insulated from each other through the insulating pattern formed in the upper and lower conductive transparent electrodes 103 and 104, whereby all the unit electrodes are connected to each other in series between the upper and lower substrates, in such a way that electricity flows from one unit electrode on the upper transparent of the upper transparent electrode 101 through the grid electrode 107 to the adjacent next unit electrode of the lower transparent substrate 102, and then flows from the unit electrode of the lower transparent electrode 102 to the next unit electrode of the upper transparent substrate 101.

In other words, the plurality of unit electrodes, each consisting of the negative electrode and the counter electrode 106 corresponding thereto, are formed on the large-area upper and lower transparent substrates 101 and 102, and the grid electrodes 107 are formed between the unit electrodes, in such a way that the adjacent unit electrodes are insulated from each other by the etched insulating patterns 121, but two unit electrodes adjacent to each other between the upper and lower substrates are connected to each other, whereby all the dye-sensitized solar cell units are connected to each other in series.

With respect to the flow of electricity of the dye-sensitized solar cell module according to the second embodiment, electricity flows only through the grid electrodes 107, because the upper and lower transparent electrodes and the grid electrodes 107 are connected with each other, and the unit electrodes are electrically insulated from each other. Specifically, electricity flows from one unit electrode of the lower substrate through the grid electrode 107 to the counter electrode of an adjacent unit electrode, and then flows from the counter electrode 106 through the grid electrode 107 to the negative electrode of the next unit electrode. In other words, electricity flows in a zigzag pattern, and thus all of the unit electrodes are connected with each other in series.

In the first and second embodiments of the present invention, the etched insulating pattern 121 is formed by printing a shape corresponding to the insulating pattern 121 on transparent paper with black ink, attaching the printed paper to a special resin such as Trepal paper, exposing the resin to light, developing the exposed resin, attaching the developed resin to the upper and lower conductive transparent electrodes 103 and 104, and strongly spraying abrasive particles, including alumina, onto the substrate using a sand blaster.

More specifically, a pattern to be etched is first printed on a transparent plastic film, paper or tracing paper (hereinafter, referred to as “paper”) with black ink using a laser printer. The printed paper is attached to UV-curable Trepal paper, which is then exposed to UV radiation. The printed paper is detached from the exposed Trepal paper, is developed in a developing solution, and is chemically treated to form a pattern to be etched. The treated paper is attached to a substrate to be etched, and abrasive particles are sprayed onto the substrate using a sand blaster.

Then, as an etched pattern having suitable depth is obtained, the spraying is stopped, and the Trepal paper is removed. In this way, it is possible to easily form an etched pattern having a complicated shape. Herein, it is possible to omit some of the intermediate processes, if necessary. Also, it is possible to use resin other than Trepal resin, as long as it has the same photochemical effect as the Trepal paper. Moreover, it is possible to directly form the etched pattern without resin using a sand blast, the position of which can be controlled.

Meanwhile, the grid electrodes 107 are formed corresponding to the shape and position of the unit electrodes, each consisting of the negative electrode and the counter electrode 106, such that the photogenerated electrons are efficiently collected. Generally, dye-sensitized solar cell units, each comprising one unit electrode, are arranged in a longitudinal direction, as shown in FIG. 5, and thus the grid electrodes 107 are formed between the solar cell units in the same or similar shapes in the longitudinal direction, such that they collect all electrons photogenerated in the dye-sensitized solar cell units and efficiently move the collected electrons in a specific direction. Herein, the grid electrodes 107 may be formed to have a linear pattern, a dotted pattern or a planar pattern, but are preferably formed in the linear pattern in order to transfer electrons in a specific direction.

Meanwhile, the connecting electrodes 108 are electrically connected with the ends of the grid electrodes 107, such that they efficiently transfer electrons moved from the grid electrodes 107 to the outside. Also, the connecting electrodes 107 serve to connect the dye-sensitized solar cell units to each other. Herein, the connecting electrodes 108 are preferably formed in a linear pattern in order to more efficiently transfer electrons.

In other words, the grid electrodes 107 act as passages for efficiently transferring electrons generated in the solar cell units to the outside, and the connecting electrodes 108 act to connect the solar cell units to each other at the outermost portion of the solar cell units.

Particularly, the grid electrodes 107 and the connecting electrodes 108 are carbon nanotube electrodes made of carbon nanotube layers. Accordingly, an electrically and chemically stable module can be provided, because dissolution in the electrolyte 109, and deterioration resulting from oxidation, which are problems occurring in the prior metal electrodes, are eliminated using generally flexible, electrically conductive carbon nanotubes as the grid electrodes 107 and the connecting electrodes 108.

The carbon nanotube layer of the carbon nanotube electrode is imparted with the desired electrical conductivity by adjusting the composition of carbon nanotubes, the binder, and additives. The carbon nanotube layer has an electrical conductivity of 10⁻¹ to 10⁴ Ω⁻¹cm⁻¹. A carbon nanotube paste for forming this carbon nanotube layer is prepared by mixing carbon nanotubes with carbon- or metal-based additives and a polymer binder such as CMC (carboxyl methyl cellulose) or PVDF using mechanical or chemical means, including a ball mill, a high-energy ball mill, ultrasonic waves, a grinder and a V-mixer, in which the content of the binder in the paste is 0.5-90 wt %.

Also, the carbon nanotube layer formed using the carbon nanotube paste is formed in a dotted pattern, a linear pattern or a planar pattern according to film forming methods, including a doctor blade method, a screen printing method, a spray method, a spin coating method and a painting method. The carbon nanotube layer has a thickness ranging from 100 nm to 1 mm, and can be formed to have a transmission rate ranging from transparency to opacity. Particularly, when it is formed in a planar pattern, the nanotube paste can be applied over a wide surface having an area of less than 1 m′ using the spray method.

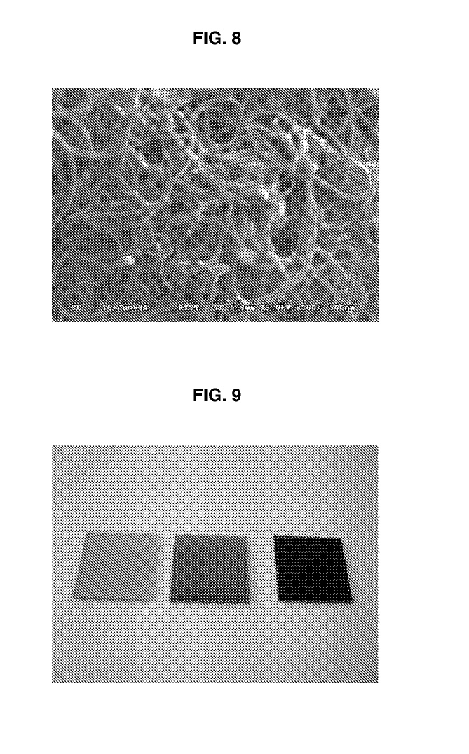

FIG. 8 is an electron microscope photograph of a carbon nanotube electrode layer prepared using carbon nanotubes (multi-wall carbon nanotubes) and a CMC binder. As can be seen in FIG. 8, the carbon nanotube electrode layer is porous and has a large surface area.

Herein, the carbon nanotube layer is formed by mixing carbon nanotube powder with additives and a suitable binder, such as CMC or PVDF, in a solvent such as water or DMP, to prepare a paste, and applying the paste on the lower substrate according to the pattern using methods, including screen printing, doctor blading, spin coating, spray coating, and painting.

The carbon nanotube layer in the present invention can be made such that it is porous, by reducing the content of the binder to 0.5% to minimize the binding between carbon nanotubes in order to maximize the surface area of the carbon nanotube layer, or such that it has a relative density approaching 100% in order to achieve high electrical conductivity. Moreover, as shown in FIG. 9, the carbon nanotube layer can also be prepared either in the form of a very thin film having a thickness of less than 1 μm to render it transparent, or in the form of a thin film or thick film having a thickness of 1 μm to 1 mm in order to completely absorb all solar energy.

The preparation of the carbon nanotube paste for forming this carbon nanotube layer can be performed either by mixing raw materials using a mechanical apparatus or method, including a general ball mill, a high-energy ball mill, such as a planetary ball mill, a vibration mill or attrition mill, a V-mixer, a grinder, stirring, and ultrasonic mixing, or by a mixing method involving chemical mechanisms together with mechanical mechanisms.

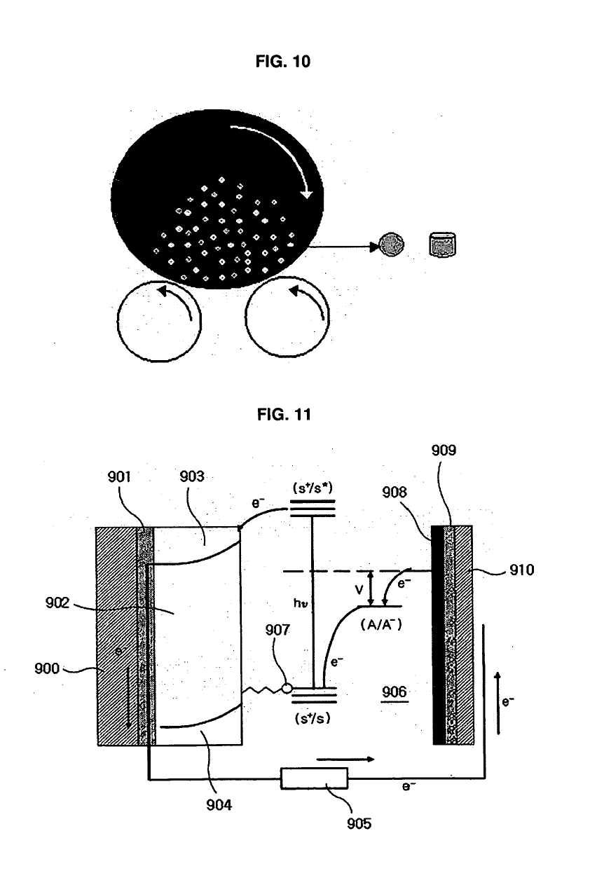

As a typical example of such a mixing method, one example of preparing the carbon nanotube paste using a ball mill is as follows. Carbon nanotube powder, having a mean diameter of 10-20 nm and a mean length of 5 μm, distilled water, as a solvent, and CMC powder, as a binder, were mixed with each other at a weight ratio of 10:88.5:1.5 using a grinder or ball mill to prepare a primary paste. Then, the paste was placed into a ball mill machine together with circular or cylindrical balls, and mixed for 24 hours while the ball mill machine was rotated, thus preparing a final uniform paste. FIG. 10 is a schematic diagram showing such a ball mill process. In tests relating to the present invention, it could be seen that the cylindrical balls provided excellent mixing compared to circular balls.

The carbon nanotube electrodes made of the carbon nanotube layer according to the present invention have excellent electrical conductivity. Thus, unlike the prior example of forming electrodes on conductive substrates in the prior solar cells, the carbon nanotube electrodes can be formed not only on conductive glass or plastic substrates having a transparent conductive film coated thereon, but also on non-conductive glass substrates, insulating substrates, including alumina substrates, and plastic substrates, including PET.

As one example thereof, carbon nanotube electrodes having an electrical conductivity of 100 Ω/cm² could be formed by coating a carbon nanotube layer on each of a transparent PET film, a glass substrate and an alumina substrate to a thickness of 20 μm using the screen coating method. When the formed carbon nanotube electrodes were applied as the counter electrodes 106 in a dye-sensitized solar cell having an N719 dye, an efficiency of 8% could be obtained.

Referring to FIGS. 4 and 6 again, in the dye-sensitized solar cell module comprising carbon nanotube electrodes according to the preferred embodiments of the present invention, an insulating film 111 for electrical insulation is preferably further formed in the electrolyte between the unit electrodes.

In this respect, the insulating film 111 is preferably formed of a thermosetting or UV-curable adhesive, or is formed of a carbon nanotube insulation layer containing the adhesive. The thermosetting or UV-curable adhesive serves to bond the upper and lower transparent substrates 101 and 102 to each other and, at the same time, serves as the insulating film 111 between the unit electrodes. Also, the carbon nanotube insulation layer containing the thermosetting or UV-curable adhesive is used to bond the upper and lower transparent substrates 101 and 102 to each other by forming the carbon nanotube insulation layer between the unit electrodes, applying the thermosetting or UV-curable adhesive on the upper and lower transparent electrodes 103 and 104 such that it is placed on the edge of the carbon nanotube insulation layer, and then curing the applied adhesive.

The insulating film 111 is formed to provide insulation such that direct electrical connection between the unit electrodes, i.e., the dye-sensitized solar cell units, is prevented. Also, the carbon nanotube insulation layer preferably consists of a mixture of carbon nanotubes, a binder, and additives. Specifically, the carbon nanotube insulation layer 111 has a composition in which a non-conductive polymer binder, such as CMC or PVDF, and a non-conductive inorganic material, including SiO₂ or TiO₂, are added to carbon nanotubes in an amount of more than 10 wt %, such that the carbon nanotube insulation layer has an electrical resistance of more than 1 kΩm.

Meanwhile, FIG. 11 schematically shows the operating principle of a dye-sensitized solar cell device having carbon nanotubes.

Referring to FIG. 11, when solar light is incident on the device, electrons in filled orbitals in a photosensitized dye 907 are excited to empty orbitals, and the excited electrons move through a porous TiO₂ electrode 902 and a conductive transparent electrode 901 to the outside. Meanwhile, the orbitals in the photosensitized dye 907, from which the electrons left, are filled by the transfer of electrons from ions in an electrolyte 906, which have received electrons from a counter electrode consisting of a carbon nanotube 908 and a transparent electrode 909. In FIG. 11, reference numeral 900 denotes an upper transparent substrate, 903 the conduction band of the porous TiO₂ electrode, 904 the valance band of the porous TiO₂ electrode, 905 an external electric load, and 910 a lower transparent or non-transparent substrate.

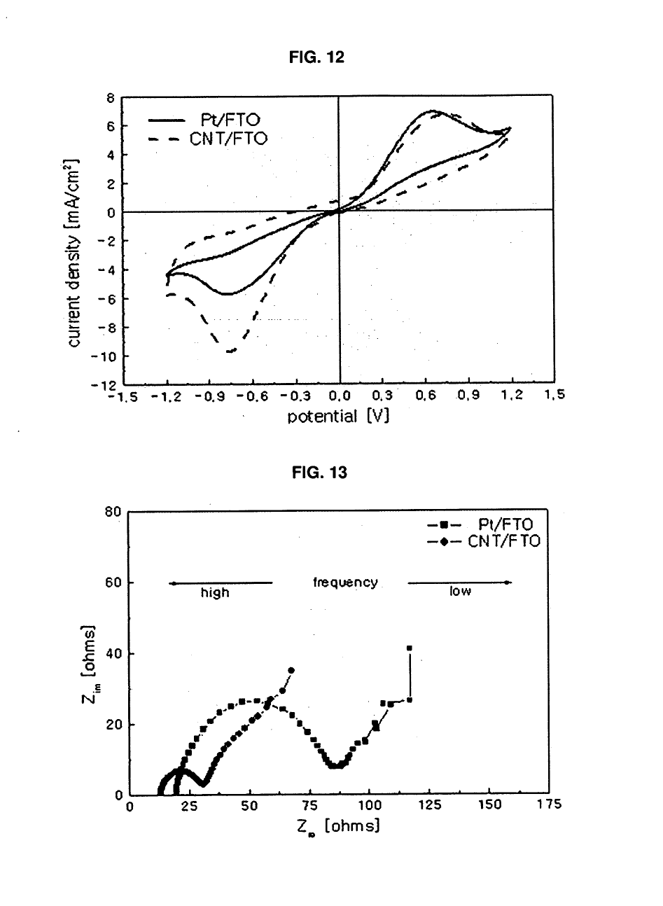

FIG. 12 shows the results of cyclic voltammetry (CV) measurement of the oxidation-reduction reaction of an electrolyte for the prior platinum electrode and a carbon nanotube electrode. Herein, as a substrate for the platinum and carbon nanotube electrodes for CV measurement, FTO was used, and as a counter electrode, a platinum (Pt) plate (2.5×2.5 cm²) was used.

Referring to FIG. 12, the intensity of electric current represents the reaction rate of the electrodes, and J-V, i.e., an internal area formed by the peak current value and the peak voltage value, means the total amount of reaction. As can be seen in FIG. 12, as the reaction rate becomes higher and the reaction amount increases, the area depicted by the left curve, which is a graph showing the results of a reduction reaction, becomes larger, and the peak also becomes larger. Thus, the carbon nanotube (CNT) electrode is notably superior to the platinum (Pt) electrode.

FIG. 13 shows impedance characteristics appearing when an alternating current voltage of 100 mHz-100 kHz was applied to the prior platinum electrode and the carbon nanotube electrode in a state in which a direct current voltage of −0.5V was applied thereto such that a reaction could occur.

Referring to FIG. 13, the smaller area of the half circle shown on the leftmost side of the curve means lower electrical resistance to an oxidation-reduction reaction caused by a catalyst. As can be seen in FIG. 13, the carbon nanotube (CNT) electrode has a reaction resistance significantly lower than that of the platinum (Pt) electrode, suggesting that a catalytic reaction on the carbon nanotube electrode can rapidly occur.

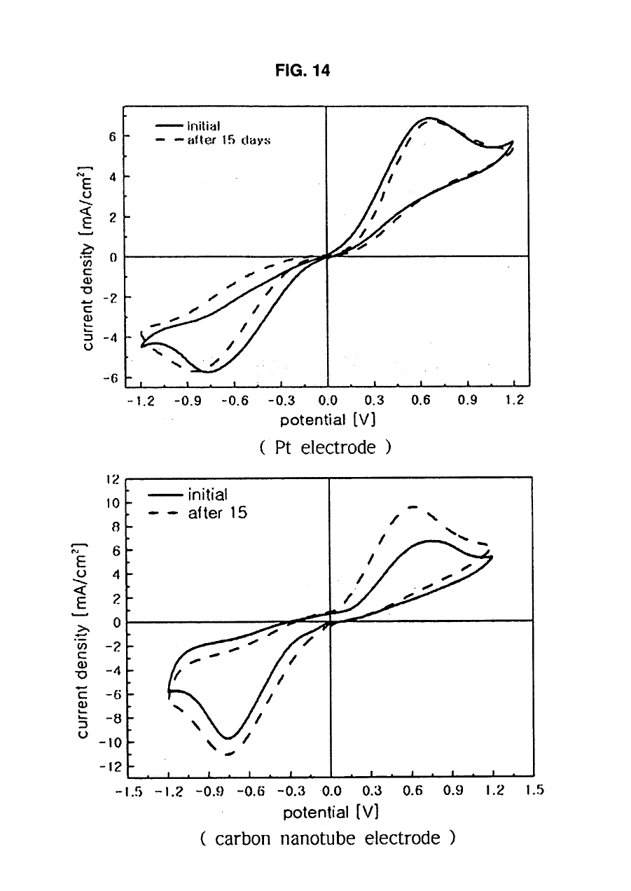

FIG. 14 shows the results of cyclic voltammetry (CV) measurement conducted at the initial stage and after 15 days of an oxidation-reduction reaction of an electrolyte in order to assess the stabilities of the prior platinum electrode and the carbon nanotube electrode.

As can be seen in FIG. 14, in the case of the platinum electrode, Vpeak was increased, and little or no change in Ipeak occurred, whereas, in the case of the carbon nanotube electrode, Vpeak remained almost constant, but Ipeak visibly increased.

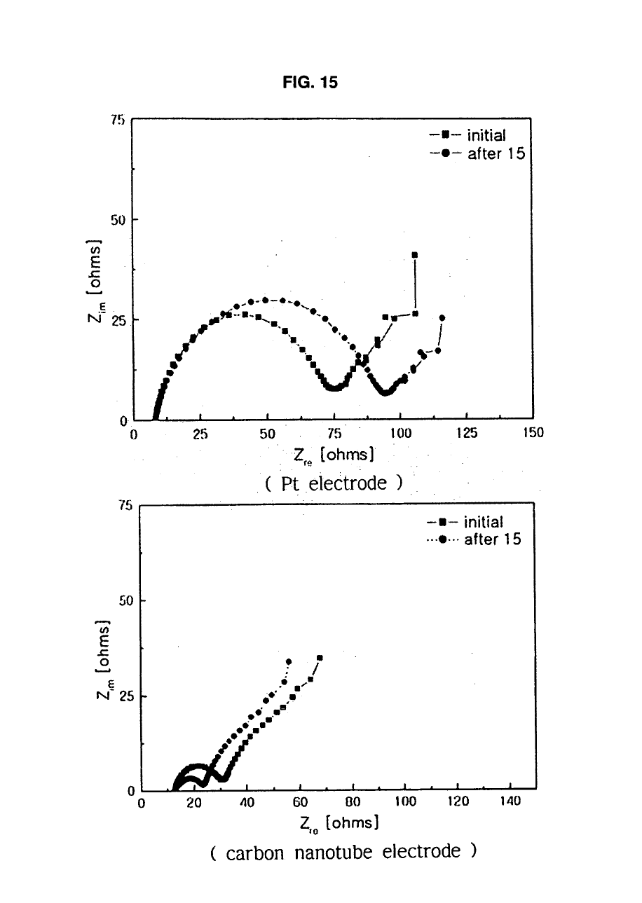

FIG. 15 shows impedance characteristics measured at the initial stage and 15 days after cell fabrication in order to assess the stabilities of the prior platinum electrode and the carbon nanotube electrode. A direct current voltage of −0.5V was applied such that a reaction could occur, and measurements were conducted in a frequency range of 100 mHz-100 kHz.

Referring to FIG. 15, like the measurement results of cyclic voltammetry (CV), the platinum electrode showed an increase in reaction resistance from about 67Ω (ohms) to 86Ω at 15 days after completion of the cell, whereas the carbon nanotube (CNT) electrode showed a reduction from about 18Ω to 10Ω.

From the results of FIGS. 14 and 15, the prior platinum (Pt) electrode showed deteriorated characteristics, which are can be expected by any person skilled in the art, whereas the carbon nanotube (CNT) electrode showed exceptional results in that the catalytic characteristics and electrode resistance characteristics improved, rather than deteriorated, with the passage of time. The prior platinum electrode forms complexes by reaction with iodine ions during an electrode reaction process, resulting in the inactivation of the surface, and reduces the efficiency of the solar cell due to a reduction in adhesion between the platinum electrode and the FTO substrate.

Recently, to solve these problems with platinum, there has been an attempt to use an acetonitrile-based special electrolyte, which has high ion conductivity and volatility. However, this attempt still does not solve the fundamental problem of reduced efficiency of the solar cell. From this viewpoint, the CV and impedance characteristics of the carbon nanotube electrode indicate that the carbon nanotube electrode is excellent for use as a counter electrode material for solar cells, because it solves the problems with the prior platinum electrode, and furthermore, has a direct effect of improving the efficiency of the solar cell.

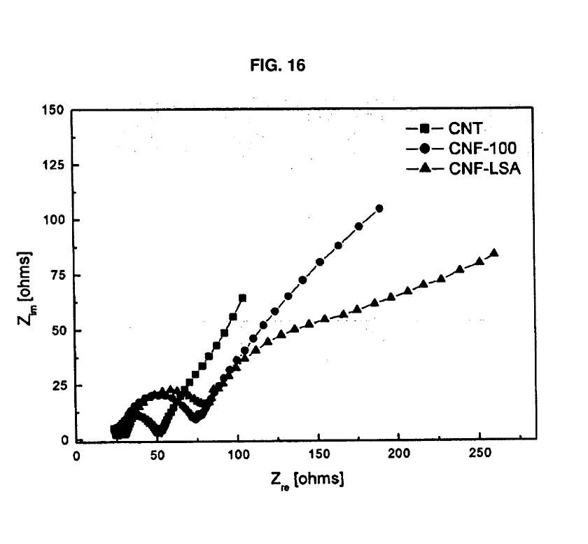

FIG. 16 shows the impedance spectral characteristics of three different carbon nanotubes.

Referring to FIG. 16, as in the case of CV, the carbon nanotube (CNT) having the smallest diameter has the lowest reaction resistance, suggesting that it is the best electrode for solar cells.

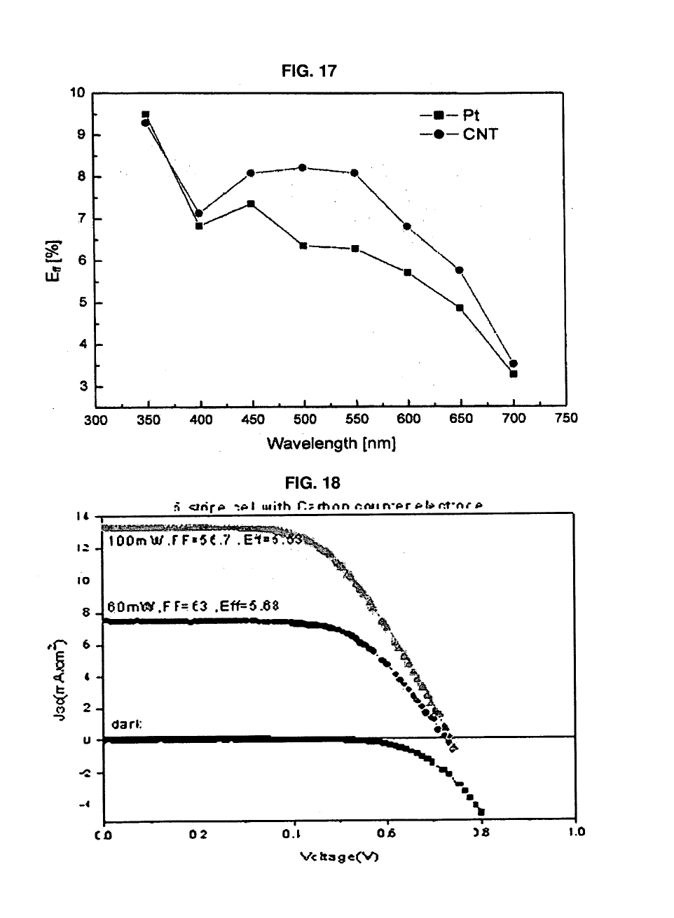

FIG. 17 shows the change in solar cell efficiency as a function of the optical wavelengths of the prior platinum electrode and the carbon nanotube electrode.

As shown in FIG. 17, in almost all wavelength regions except for a UV wavelength of 350 nm, the solar cell comprising the carbon nanotube (CNT) counter electrode has an efficiency higher than that of the platinum (Pt) electrode.

FIG. 18 shows the efficiency of a dye-sensitized solar cell module comprising carbon nanotube electrodes connected in parallel. As shown in FIG. 18, the dye-sensitized solar cell module comprising carbon nanotube electrodes has a significantly high efficiency of about 5.5%. Thus, it is expected that the dye-sensitized solar cell module comprising carbon nanotube electrodes can be formed to have a large area and used in practice.

While preferred embodiments of the present invention have been shown and described, it will be apparent to those skilled in the art that many changes and modifications may be made without departing from the invention in its broader aspects. The appended claims are intended to cover, therefore, all such changes and modifications as fall within the true spirit and scope of the invention.

### INDUSTRIAL APPLICABILITY

As described above, the present invention can provide a high-efficiency, large-area, dye-sensitized solar cell comprising carbon nanotubes by forming a plurality of dye-sensitized solar cell units in a module arrangement, and forming grid electrodes and connection electrodes for the collection and movement of electrons. Thus, the present invention has high practical utility.

Also, the dye-sensitized solar cell module comprising carbon nanotube electrodes according to the present invention has the following advantages and effects as a result of the use of carbon nanotubes as counter electrodes, grid electrodes and connecting electrodes.

First, the total surface area of the carbon nanotube electrode, which causes catalytic actions, is much larger than that of the prior platinum electrode, and thus the carbon nanotube electrode has a high catalytic rate for oxidation-reduction and excellent electrical conductivity. Accordingly, it enables electron transfer in the solar cell device to be rapidly achieved, thus increasing the efficiency of the solar cell.

Second, because carbon nanotubes have high electrical conductivity, comparable to that of metals, they eliminate the need to use transparent electrodes, which must be used with the prior platinum electrodes, and thus it is possible to use, in addition to glass substrates, various kinds of substrates having high electrical insulating properties. Due to this increase in the width of selection of the underlying substrates, glass substrates can also be used, and it is possible to use various manufacturing processes.

Third, in a process of coating the carbon nanotube layer on a substrate, a screen printing method or a spray method, for example, can be used, and thus the carbon nanotube layer can be coated uniformly on a substrate having a large area. This makes it possible to produce large-area solar cells, making it possible to produce a large-area solar cell module, resulting in a decrease in the price of the module and an increase in the efficiency of the solar cell.

Fourth, because grid electrodes and connecting electrodes are made of flexible and electrically conductive carbon nanotube electrodes, these electrodes do not undergo dissolution in an electrolyte, or deterioration resulting from oxidation or the like, which are problems with the prior metal electrodes. Thus, an electrically and chemically stable solar cell module can be provided.

What is claimed is:

1. A dye-sensitized solar cell module having carbon nanotube electrodes, the solar cell module comprising:
upper and lower transparent substrates;
conductive transparent electrodes formed on the inner surfaces of the upper and lower transparent substrates;
a plurality of porous oxide semiconductor negative electrodes formed on the upper conductive transparent electrode at a constant interval and having a dye adsorbed on the surface thereof;
counter electrodes formed on the lower conductive transparent electrode in a thin film form and made of a carbon nanotube layer as a positive electrode portion corresponding to the negative electrodes;
grid electrodes formed on the upper and lower conductive transparent electrodes between unit electrodes, each consisting of the negative electrode and the counter electrode corresponding thereto, the grid electrodes serving to collect electrons generated by photosensitization;
connecting electrodes formed on the upper and lower conductive transparent electrodes and electrically connected with the grid electrode so as to transfer electrons moved from the grid electrodes to the outside; and
electrolyte placed between the negative electrodes and the counter electrodes.

2. The dye-sensitized solar cell module of claim 1, wherein the grid electrodes on the negative electrode side and the grid electrodes on the counter electrode side are electrically insulated from each other, such that the unit electrodes are connected to each other in parallel.

3. The dye-sensitized solar cell module of claim 2, wherein an insulating film for electrical insulation is further formed in the electrolyte between the unit electrodes.

4. The dye-sensitized solar cell module of claim 3, wherein the insulating film consists of a thermosetting or UV-curable adhesive, or a carbon nanotube insulation layer containing the adhesive, the carbon nanotube insulation layer having an electrical resistance of more than 1 kΩcm.

5. The dye-sensitized solar cell module of claim 4, wherein the carbon nanotube insulation layer has a composition in which a non-conductive polymer binder, such as CMC or PVDF, and a non-conductive inorganic material, including SiO₂ or TiO₂, are added to carbon nanotubes in an amount of more than 10%.

6. The dye-sensitized solar cell module of claim 2, wherein the unit electrodes constitute a plurality of sections, and an etched insulating pattern is formed in the upper and lower conductive transparent electrodes, such that the sections are electrically insulated from each other.

7. The dye-sensitized solar cell module of claim 1, wherein an etched insulating pattern is formed in the upper and lower conductive transparent electrodes, such that the unit electrodes are electrically insulated on the upper and lower conductive transparent electrodes, such that electricity flows through the grid electrodes, whereby the unit electrodes are connected to each other in series.

8. The dye-sensitized solar cell module of claim 7, wherein an insulating film for electrical insulation is further formed in the electrolyte between the unit electrodes.

9. The dye-sensitized solar cell module of claim 8, wherein the insulating film consists of a thermosetting or UV-curable adhesive, or a carbon nanotube insulation layer containing the adhesive, the carbon nanotube insulation layer having an electrical resistance of more than 1 kΩcm.

10. The dye-sensitized solar cell module of claim 9, wherein the carbon nanotube insulation layer has a composition in which a non-conductive polymer binder, such as CMC or PVDF, and a non-conductive inorganic material, including SiO₂ or TiO₂, are added to carbon nanotubes in an amount of more than 10%.

11. The dye-sensitized solar cell module of claim 1, wherein the carbon nanotube electrodes consisting of the carbon nanotube layer have an electrical conductivity of 10⁻¹ to 10⁴ Ω⁻¹cm⁻¹.

12. The dye-sensitized solar cell module of claim 1, wherein the grid electrodes or connecting electrodes consist of a carbon nanotube layer.

13. The dye-sensitized solar cell module of claim 1, wherein a carbon nanotube paste for forming the carbon nanotube layer is prepared by mixing carbon nanotubes with a carbon- or metal-based additive or a polymer binder such as CMC (carboxyl methyl cellulose) or PVDF using mechanical or mechanochemical methods, including a ball mill, a high-energy ball mill, ultrasonic waves, a grinder, and a V-mixer, in which the content of the binder in the paste is 0.5-90 wt %.

14. The dye-sensitized solar cell module of claim 1, wherein the carbon nanotube layer is formed in a dotted pattern, a linear pattern or a planar pattern using film forming methods, including a doctor blade method, a screen printing method, a spray method, a spin coating method and a painting method, and has a thickness ranging from 100 nm to 1 mm.

15. A method of manufacturing a dye-sensitized solar cell module using carbon nanotube electrodes, the method comprising:
a first step of preparing a carbon nanotube paste;
a second step of forming conductive transparent electrodes on the upper surfaces of upper and lower transparent substrates;
a third step of etching the surfaces of the upper conductive transparent electrodes to form an etched insulating pattern;
a fourth step of forming, on the upper conductive transparent electrode from the third step, a specific pattern of porous oxide semiconductor negative electrodes having a dye adsorbed on the surface thereof, and depositing a carbon nanotube layer on the lower conductive transparent electrode using the carbon nanotube paste, to form counter electrodes as a positive electrode portion corresponding to the negative electrodes;
a fifth step of forming grid electrodes on the upper and lower conductive transparent electrodes between unit electrodes, each consisting of the negative electrode and the counter electrode, and forming connecting electrodes connecting the grid electrodes to each other;
a sixth step of forming an insulating film between the unit electrodes and bonding the upper and lower substrate to each other; and
a seventh step of injecting an electrolyte between the upper and lower substrates.

16. The method of claim 15, wherein the carbon nanotube paste in the first step is prepared by mixing carbon nanotubes with a carbon- or metal-based additive or a polymer binder such as CMC (carboxyl methyl cellulose) or PVDF using mechanical or mechanochemical methods, including a ball mill, a high-energy ball mill, ultrasonic waves, a grinder, and a V-mixer, in which the content of the binder in the paste is 0.5-90 wt %.

17. The method of claim 15, wherein the etched insulating pattern in the third step is formed by printing a shape corresponding to the insulating pattern on transparent paper with black ink, attaching the printed paper to a special resin such as Trepal paper, exposing the resin to light, developing the exposed resin, attaching the developed resin to the upper and lower conductive transparent electrodes, and strongly spraying abrasive particles, including alumina, onto the substrate using a sand blaster.

18. The method of claim 15, wherein the negative electrodes and counter electrodes in the fourth step and the grid electrodes in the fifth step are formed using film forming methods, including a doctor blade method, a screen printing method, a spray method, a spin coating method and a painting method, in a dotted pattern, a linear pattern or a planar pattern, and have a thickness ranging from 100 nm to 1 mm.

19. A dye-sensitized solar cell module comprising a plurality of dye-sensitized solar cell units, each comprising:
upper and lower transparent substrates; a conductive transparent electrode formed on the inner surface of the upper transparent substrate; a porous oxide semiconductor negative electrode formed on the upper conductive transparent electrode and having a dye adsorbed on the surface thereof; a counter electrode formed on the lower conductive transparent electrode in a thin film form and made of a carbon nanotube layer as a positive electrode portion corresponding to the negative electrode; and an electrolyte placed between the negative electrode and the counter electrode, the dye-sensitized solar cell units being connected to each other in parallel or in series using connecting electrodes and grid electrodes,
wherein the connecting electrodes and the grid electrodes consist of carbon nanotube electrodes.

20. The dye-sensitized solar cell module of claim 19, wherein the carbon nanotube electrode have an electrical conductivity ranging from 10⁻¹ to 10⁴ Ω⁻¹cm⁻¹.

21. The dye-sensitized solar cell module of claim 19, wherein a carbon nanotube paste for forming the carbon nanotube electrodes is prepared by mixing carbon nanotubes with a carbon- or metal-based additive or a polymer binder such as CMC (carboxyl methyl cellulose) or PVDF using mechanical or mechanical or chemical methods, including a ball mill, a high-energy ball mill, ultrasonic waves, a grinder, and a V-mixer, in which the content of the binder in the paste is 0.5-90 wt %.

22. The dye-sensitized solar cell module of claim 19, wherein the carbon nanotube electrodes are formed in a dotted pattern, a linear pattern or a planar pattern using film forming methods, including a doctor blade method, a screen printing method, a spray method, a spin coating method and a painting method and has a thickness ranging from 100 nm to 1 mm.

23. A dye-sensitized solar cell module comprising a plurality of dye-sensitized solar cell units, each comprising:
upper and lower transparent substrates; a conductive transparent electrode formed on the inner surface of the upper transparent substrate; a porous oxide semiconductor negative electrode formed on the upper conductive transparent electrode and having a dye adsorbed on the surface thereof; a counter electrode formed on the lower conductive transparent electrode in a thin film form and made of a carbon nanotube layer as a positive electrode portion corresponding to the negative electrode; and an electrolyte placed between the negative electrode and the counter electrode, the dye-sensitized solar cell units being connected to each other in parallel or in series using connecting electrodes and grid electrodes,
wherein an insulating film for providing insulation between the solar cell units is further formed between the unit solar cells.

24. The dye-sensitized solar cell module of claim 23, wherein the insulating film consists of a carbon nanotube insulation film, which has an electrical resistance of more than 1 kΩcm.

25. The dye-sensitized solar cell module of claim 24, wherein the carbon nanotube insulation film has a composition in which a non-conductive polymer binder, such as CMC or PVDF, and a non-conductive inorganic material, including SiO₂ or TiO₂, are added to carbon nanotubes in an amount of more than 10%.
